(19) United States
(12) Patent Application Publication
(10) Pub. No.: US 2015/0221815 A1
(43) Pub. Date: Aug. 6, 2015

(54) SOLID STATE LIGHTING DEVICE WITH REDUCED LUMINOUS FLUX DROP AT ELEVATED TEMPERATURE

(71) Applicant: Cree, Inc., Durham, NC (US)

(72) Inventors: David Clatterbuck, Raleigh, NC (US); Harry Seibel, Durham, NC (US); Romit Dhar, Raleigh, NC (US); Robert David Schmidt, Wake Forest, NC (US); Daniel Carleton Driscoll, Raleigh, NC (US); Michael John Bergmann, Raleigh, NC (US)

(21) Appl. No.: 14/170,176

(22) Filed: Jan. 31, 2014

(51) Int. Cl. H01L 33/00; H01L 33/12; H01L 27/15; H01L 33/32; H01L 33/50

(52) U.S. Cl. CPC H01L 33/0025; H01L 33/32; H01L 33/325; H01L 33/507; H01L 27/15; H01L 33/12; F21Y 2101/02

(57) ABSTRACT

A solid state light emitting device includes a solid state light emitter and a lumiphoric material that are selected for use with one another to provide light emissions with improved (i.e., reduced) thermal droop A solid state emitter having a short peak emission wavelength (e.g., in a visible range at or below 440 nm) seemingly less than optimal at room temperature for use with a particular lumiphor can trigger more efficient stimulation of lumiphor emissions at high temperatures. Enhanced epitaxial structures also inhibit decrease of radiant flux by LEDs at elevated temperatures.

### TECHNICAL FIELD

Subject matter herein relates to solid state lighting devices, including devices with lumiphors arranged to be stimulated by electrically activated solid light emitters, and relates to associated methods of making and using such devices.

### BACKGROUND

Lumiphoric materials (also known as lumiphors) are commonly used with solid state emitters to produce a variety of emissions such as colored (e.g., non-white) or white light (e.g., perceived as being white or near-white). Electrically activated solid state emitters such as LEDs or lasers may be used to provide white light (e.g., perceived as being white or near-white), and have been investigated as potential replacements for white incandescent lamps. Solid state emitters may have associated filters that alter the color of emitted light and/or include lumiphoric materials that absorb a portion of emissions having a first peak wavelength emitted by the emitter and re-emit light having a second peak wavelength that differs from the first peak wavelength. Phosphors, scintillators, and lumiphoric inks are common lumiphoric materials. Light perceived as white or near-white may be generated by a combination of red, green, and blue (“RGB”) emitters, or, alternatively, by combined emissions of a blue light emitting diode (“LED”) and a lumiphor such as a yellow phosphor. In the latter case, a portion of the blue LED emissions pass through the phosphor, while another portion of the blue LED emissions is downconverted to yellow, and the blue and yellow light in combination provide light that is perceived as white. Another approach for producing white light is to stimulate phosphors or dyes of multiple colors with a violet or ultraviolet LED source.

A representative example of a white LED lamp includes a package of a blue LED chip (e.g., made of InGaN and/or GaN) combined with a lumiphoric material such as a phosphor (typically YAG:Ce) that absorbs at least a portion of the blue light (first peak wavelength) and re-emits yellow light (second peak wavelength), with the combined yellow and blue emissions providing light that is perceived as white or near-white in character. If the combined yellow and blue light is perceived as yellow or green, it can be referred to as ‘blue shifted yellow’ (“BSY”) light or ‘blue shifted green’ (“BSG”) light. Addition of red spectral output from an emitter or lumiphoric material (e.g., to yield a “BSY+R” lighting device) may be used to increase the warmth of the aggregated light output and better approximate light produced by incandescent lamps.

Many modern lighting applications require high power emitters to provide a desired level of illumination, but high power devices draw large currents and generate significant amounts of heat. The luminous flux of lumiphor-converted solid state lighting devices (e.g., LED-based devices arranged to stimulate lumiphors) typically decreases as the temperature of the device increases, with such luminous flux decrease being attributable in part to reduced radiant flux of an electrically activated solid state emitter at high temperature, and in part to reduced efficiency of a lumiphor at converting emissions of an electrically activated solid state light emitter to other wavelengths. Since the temperature of solid state lighting devices is elevated during operation, this leads to lower luminous flux (also known as thermal droop) during operating conditions. Beyond the undesirable reductions in luminous flux, reduction in thermal flux of one or more emitter components can also cause undesirably perceptible color shifts at elevated temperatures, particularly in lighting devices with multiple emitter components.

The art continues to seek improved solid state lighting devices having light emissions with improved thermal droop, wherein luminous flux does not decrease as quickly with elevated temperature in comparison to conventional solid state lighting devices, as well as solid state lighting devices with improved stability of output color at elevated temperatures.

### SUMMARY

The present invention relates in various aspects to solid state (e.g., LED) lighting devices including at least one electrically activated solid state emitter element and at least one lumiphoric material that are selected for use with one another to provide light emissions with improved (i.e., reduced) thermal droop. Additional aspects of the invention relate to epitaxial structures and electrically activated solid state light emitters (e.g., LEDs) including such epitaxial structures that inhibit decrease of radiant flux by such emitters at elevated temperatures.

In one aspect, the invention relates to a solid state lighting device comprising a lumiphoric material having a peak emission wavelength in a yellow range arranged to receive and be excited by light emissions of at least one electrically activated solid state light emitter having a peak wavelength in a range of from 428 nm to 440 nm at a solid state light emitter temperature of 25° C., wherein the lumiphoric material comprises a peak excitation wavelength that exceeds the peak emission wavelength of the at least one electrically activated solid state light emitter by at least 20 nm.

In another aspect, the invention relates to a solid state lighting device comprising a lumiphoric material arranged to receive and be excited by light emissions of at least one electrically activated solid state light emitter, wherein the at least one electrically activated solid state light emitter is arranged to emit light in a blue wavelength range, the lumiphoric material is arranged to emit light in a yellow wavelength range, and the solid state lighting device exhibits at least one of the following characteristics (a) to (d): (a) a luminous flux drop of no greater than 5% when operated at an electrically activated solid state light emitter temperature of 85° C. relative to operation at an electrically activated solid state light emitter temperature of 25° C., (b) a luminous flux drop of no greater than 8% at an electrically activated solid state light emitter temperature of 105° C. relative to operation at an electrically activated solid state light emitter temperature of 25° C., (c) a luminous flux drop of no greater than 12% at an electrically activated solid state light emitter temperature of 125° C. relative to operation at an electrically activated solid state light emitter temperature of 25° C., and (d) a luminous flux drop of no greater than 17% at an electrically activated solid state light emitter temperature 150° C. relative to operation at an electrically activated solid state light emitter temperature of 25° C.

In another aspect, the invention relates to a solid state lighting device comprising at least one light emitting diode (LED) including a nominal peak emission wavelength in a range of from 428 nm to 440 nm at a LED temperature of 25° C., and a lumiphoric material arranged to receive and be excited by light emissions of the at least one LED, wherein the lumiphoric material comprises a peak excitation wavelength, and the solid state lighting device comprises at least one of the following features (a) and (b): (a) the peak excitation wavelength of the lumiphoric material exceeds the nominal peak emission wavelength by at least 15 nm, and (b) the solid state lighting device is devoid of any lumiphoric material comprising a peak excitation wavelength within 15 nm of the nominal peak emission wavelength.

In yet another aspect, the invention relates to a solid state lighting device comprising a lumiphoric material having a peak emission wavelength in a yellow range arranged to receive and be excited by light emissions of at least one electrically activated solid state light emitter having a peak emission wavelength in a blue range, wherein: aggregated emissions of the at least one electrically activated solid state light emitter and the lumiphoric material comprise (a) an high temperature luminous flux value when the at least one electrically activated solid state light emitter is operated at 85° C., and (b) a low temperature luminous flux value when the at least one electrically activated solid state light emitter is operated at 25° C., wherein relative luminous flux comprises a ratio of the high temperature luminous flux value to the low temperature luminous flux value; emissions of the at least one electrically activated solid state light emitter comprise (c) a high temperature radiant flux value when the at least one electrically activated solid state light emitter is operated at 85° C., and (d) a low temperature radiant flux value when the at least one electrically activated solid state light emitter is operated at 25° C., wherein relative radiant flux comprises a ratio of the high temperature radiant flux value to the low temperature radiant flux value; and a ratio of relative luminous flux to relative radiant flux is greater than or equal to 0.98.

In another aspect, the invention relates to a method comprising illuminating an object, a space, or an environment, utilizing a solid state lighting device as described herein.

In another aspect, any of the foregoing aspects, and/or various separate aspects and features as described herein, may be combined for additional advantage. Any of the various features and elements as disclosed herein may be combined with one or more other disclosed features and elements unless indicated to the contrary herein.

Other aspects, features and embodiments of the invention will be more fully apparent from the ensuing disclosure and appended claims.

### BRIEF DESCRIPTION OF THE DRAWINGS

FIG. 1 is a line chart providing the excitation spectrum, in normalized intensity versus wavelength (nm), for a yellow-emitting YAG:Ce phosphor, with addition of one vertical line at left representing a peak wavelength emitted by a blue LED at room temperature (e.g., 25° C.) and addition of a second vertical line at right representing peak wavelength emitted by the same blue LED at an elevated operating temperature (e.g., 85° C.).

FIG. 2 is an upper perspective view of a portion of a solid state light emitter package including a LED arranged to stimulate emissions of a lumiphoric material, with the illustrated portion being devoid of a hemispherical lens.

FIG. 3 is a side elevation view of a solid state light emitter package including the portion shown in FIG. 2, with the addition of a hemispherical lens over the LED.

FIG. 4 is a lower perspective view of the solid state light emitter package of FIG. 3.

FIG. 5 is a plot of relative luminous flux (Rel LF) versus nominal blue LED peak wavelength for white light emissions of four different groups of solid state emitter packages of a type according to FIGS. 2-3, with each package including a blue LED arranged to stimulate a yellow phosphor, and with Rel LF representing a ratio of luminous flux at 85° C. to luminous flux at 25° C.

FIG. 6 is a plot of relative radiant flux (Rel RF) versus nominal blue LED peak wavelength for blue light emissions of four different groups of solid state emitter packages of a type according to FIGS. 2-3, following removal of yellow phosphor from the LEDs, with Rel RF representing a ratio of radiant flux at 85° C. to radiant flux at 25° C.

FIG. 7 is a plot of relative luminous flux divided by relative radiant flux (Rel LF/Rel RF) versus nominal blue LED peak wavelength obtaining by dividing the Rel LF values of FIG. 5 by the corresponding Rel RF values of FIG. 6 for the emitter packages.

FIG. 8 is a plot of color shift (change in ccy) versus nominal blue peak wavelength for the white light-emitting solid state emitter packages tested in connection with FIGS. 5-7.

FIG. 9 is a plot embodying a bivariate fit of relative luminous flux (Rel LF) versus temperature stage setpoint (TStageSP) over a range of temperatures from 60° C. to 150° C. relative to a luminous flux at 25° C., for seven white light emitters each including a blue LED arranged to stimulate a yellow phosphor, with the seven white light emitters including a first comparison emitter having a nominal blue LED peak wavelength of about 444.5 nm, a second comparison emitter having a nominal blue LED peak wavelength of about 441 nm, a Cree XPGB OW third comparison emitter having a nominal blue LED peak wavelength of about 447 nm, and four emitters according to embodiments of the present invention having nominal blue LED peak wavelengths from 435 nm to 438.5 nm.

FIG. 10 is a plot of nominal blue peak wavelength (nm) versus category for the emitters of FIG. 9.

FIG. 11A is a chart including color coordinates ccy versus ccx on a portion of a CIE 1931 x,y Chromaticity Diagram for the white light emitters of FIGS. 9-10, with superimposed identification of Cree bin numbers 5A1 to 6B3 as well as larger (dashed line) bins according to ANSI C78.377A.

FIG. 11B is a portion of a CIE 1931 x,y Chromaticity Diagram with superimposed identification of Cree bin numbers 5A1 to 8C3 and color temperature lines, to provide context to the coordinates of the white light emitters plotted in FIG. 11A.

FIG. 12A is a side cross-sectional schematic view of a portion of a solid state lighting device including an electrically activated solid state light emitter (e.g., LED) and at least one lumiphor dispersed in an encapsulant material disposed over the solid state light emitter.

FIG. 12B is a side cross-sectional schematic view of a portion of a solid state lighting device including an electrically activated solid state light emitter (e.g., LED) and at least one lumiphor arranged in one or more layers spatially separated from the solid state light emitter.

FIG. 12C is a side cross-sectional schematic view of a portion of a solid state lighting device including multiple electrically activated solid state light emitters (e.g., LEDs) and at least one lumiphor dispersed in an encapsulant material disposed over the multiple solid state light emitters.

FIG. 12D is a side cross-sectional schematic view of a portion of a solid state lighting device including multiple solid state light emitters (e.g., LEDs) and at least one lumiphor arranged in one or more layers spatially separated from the multiple solid state light emitters.

FIG. 12E is a is a side cross-sectional schematic view of a portion of a solid state lighting device including multiple solid state light emitters (e.g., LEDs), with at least one solid state light emitter having a lumiphor material individually applied or coated over at least one surface of the solid state light emitter.

FIG. 13 is a side cross-sectional schematic view of an epitaxial structure of a Group-III nitride-based light emitting diode according to certain embodiments of the present invention.

### DETAILED DESCRIPTION

As noted previously, the art continues to seek improved lighting devices that address one or more limitations inherent to conventional devices. For example, it would be desirable to provide lighting devices including at least one electrically activated solid state emitter element and at least one lumiphoric material that are selected for use with one another to provide light emissions with improved (i.e., reduced) thermal droop.

In lumiphor-converted LED devices, LEDs and lumiphors are typically selected to cause a nominal peak emission wavelength of a LED to be relatively close to a peak stimulation wavelength of a corresponding lumiphor. LEDs with peak emission wavelengths greater than 441 nm are commonly used. A prime reason to attempt to match a peak emission wavelength of a LED with a peak stimulation wavelength of a lumiphor is to reduce Stokes shift losses. As an electrically activated solid state light emitter such as a blue LED heats up to an elevated temperature, the peak emission wavelength of such solid state emitter is shifted to a greater (longer) wavelength. Various aspects of the subject matter disclosed herein involve selection of at least one electrically activated solid state light emitter having a nominal (e.g., room temperature) peak emission wavelength shorter than 441 nm, which is utilized in conjunction with a lumiphoric material having a peak excitation wavelength of at least 20 nm greater (or in certain embodiments at least 15 nm greater) than the nominal peak emission wavelength of the solid state light emitter. In certain embodiments, an electrically activated solid state light emitter may be selected taking into account the expected (shifted) peak wavelength of an electrically activated solid state light emitter when operated at elevated temperature, whereby an electrically activated solid state light emitter that is seemingly less than optimal at room temperature for use with a particular lumiphor can trigger more efficient stimulation of lumiphor emissions when the solid state light emitter is operated at an elevated temperature. This effect can offset some or all of the normal loss in efficiency that may be attributable to stimulation of lumiphor emission when a lumiphor is at high temperature.

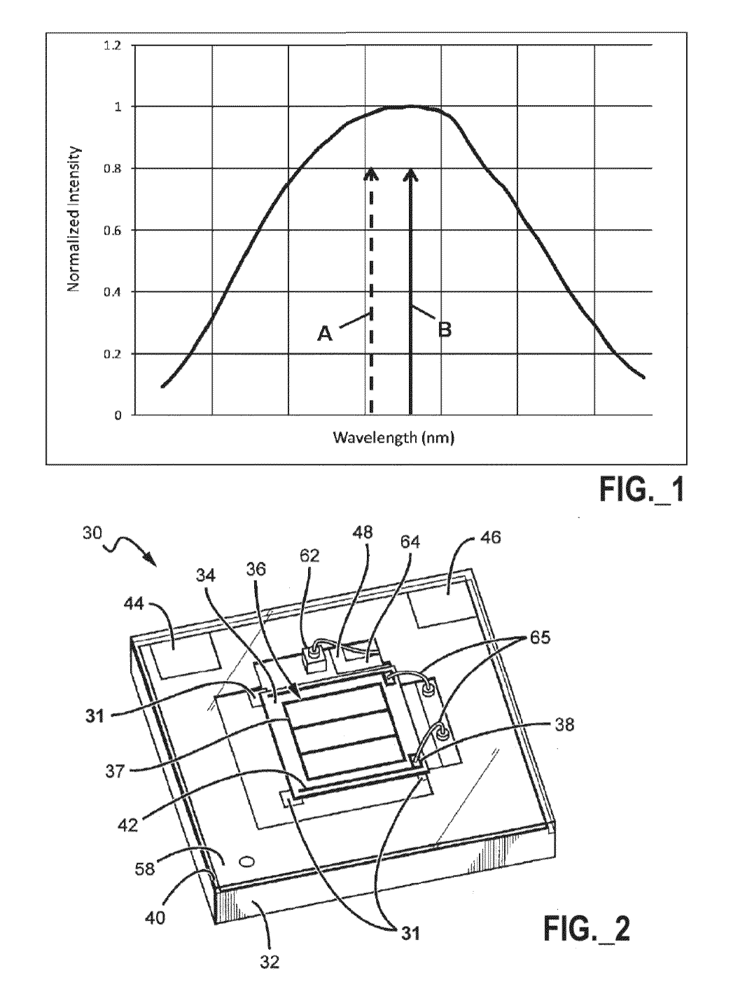

An electrically activated solid state light emitter having a lower peak emission wavelength when operated at an emitter temperature of 25° C., but having a higher peak emission wavelength at an elevated temperature (e.g., 85° C.) is depicted in FIG. 1. Such figure is a line chart providing the excitation spectrum, in normalized intensity versus wavelength (nm), for a yellow-emitting YAG:Ce phosphor. A first vertical line “A” represents a nominal peak emission wavelength of a blue LED at room temperature (e.g., 25° C.). When the blue LED is driven with greater current and attains a higher temperature (e.g. 85° C.), the peak emission wavelength of the blue LED shifts to a longer value, as represented by the second vertical line “B”, with the peak emission wavelength of the blue LED at an elevated temperature preferably shifting closer\to the peak excitation wavelength of the yellow-emitting phosphor. Aggregated emissions of the resulting lighting device include emissions of the lumiphoric material in combination with a portion of the emissions of the electrically activated solid state light emitter not absorbed by the lumiphoric material. Is to be appreciated that aspects of the invention are not limited to the foregoing specific LED and phosphor combination.

Additional aspects of the invention relate to epitaxial structures and electrically activated solid state light emitters (e.g., LEDs) including such epitaxial structures that inhibit decrease of radiant flux by such emitters at elevated temperatures.

Unless otherwise defined, terms used herein should be construed to have the same meaning as commonly understood by one of ordinary skill in the art to which this invention belongs. It will be further understood that terms used herein should be interpreted as having a meaning that is consistent with their meaning in the context of this specification and the relevant art, and should not be interpreted in an idealized or overly formal sense unless expressly so defined herein.

Embodiments of the invention are described herein with reference to cross-sectional, perspective, elevation, and/or plan view illustrations that are schematic illustrations of idealized embodiments of the invention. Variations from the shapes of the illustrations as a result, for example, of manufacturing techniques and/or tolerances, are to be expected, such that embodiments of the invention should not be construed as limited to particular shapes illustrated herein. The invention may be embodied in different forms and should not be construed as limited to the specific embodiments set forth herein. In the drawings, the size and relative sizes of layers and regions may be exaggerated for clarity.

Unless the absence of one or more elements is specifically recited, the terms “comprising,” “including,” and “having” as used herein should be interpreted as open-ended terms that do not preclude the presence of one or more elements.

It will be understood that when an element such as a layer, region, or substrate is referred to as being “on” another element, it can be directly on the other element or intervening elements may be present. Moreover, relative terms such as “on”, “above”, “upper”, “top”, “lower”, or “bottom” may be used herein to describe a relationship between one structure or portion to another structure or portion as illustrated in the figures, but it should be understood that such relative terms are intended to encompass different orientations of the device in addition to the orientation depicted in the figures. For example, if the device in the figures is turned over, structure or portion described as “above” other structures or portions would now be oriented “below” the other structures or portions.

The terms “solid state light emitter” or “solid state emitter” (which may be qualified as being “electrically activated”) may include a light emitting diode, laser diode, organic light emitting diode, and/or other semiconductor device which includes one or more semiconductor layers, which may include silicon, silicon carbide, gallium nitride and/or other semiconductor materials, a substrate which may include sapphire, silicon, silicon carbide and/or other microelectronic substrates, and one or more contact layers which may include metal and/or other conductive materials.

Solid state light emitting devices according to embodiments of the invention may include III-V nitride (e.g., gallium nitride) based LED chips or laser chips fabricated on a silicon, silicon carbide, sapphire, or III-V nitride growth substrate, including (for example) devices manufactured and sold by Cree, Inc. of Durham, N.C. Such LEDs and/or lasers may be configured to operate such that light emission occurs through the substrate in a so-called “flip chip” orientation. Such LED and/or laser chips may also be devoid of growth substrates (e.g., following growth substrate removal).

LED chips useable with lighting devices as disclosed herein may include horizontal devices (with both electrical contacts on a same side of the LED) and/or vertical devices (with electrical contacts on opposite sides of the LED). A horizontal device (with or without the growth substrate), for example, may be flip chip bonded (e.g., using solder) to a carrier substrate or printed circuit board (PCB), or wire bonded. A vertical device (without or without the growth substrate) may have a first terminal solder bonded to a carrier substrate, mounting pad, or printed circuit board (PCB), and have a second terminal wire bonded to the carrier substrate, electrical element, or PCB. Although certain embodiments shown in the figures may be appropriate for use with vertical LEDs, it is to be appreciated that the invention is not so limited, such that any combination of one or more of the following LED configurations may be used in a single solid state light emitting device: horizontal LED chips, horizontal flip LED chips, vertical LED chips, vertical flip LED chips, and/or combinations thereof, with conventional or reverse polarity

Solid state light emitters may be used individually or in groups to emit one or more beams to stimulate emissions of one or more lumiphoric materials (e.g., phosphors, scintillators, lumiphoric inks, quantum dots, day glow tapes, etc.) to generate light at one or more peak wavelength, or of at least one desired perceived color (including combinations of colors that may be perceived as white). Lumiphors may be provided in the form of particles, films, or sheets.

Inclusion of lumiphoric (also called ‘luminescent’) materials in lighting devices as described herein may be accomplished by any suitable means, including: direct coating on solid state emitters, dispersal in encapsulant materials arranged to cover solid state emitters; coating on lumiphor support elements (e.g., by powder coating, inkjet printing, or the like); incorporation into diffusers or lenses; and the like. Examples of lumiphoric materials are disclosed, for example, in U.S. Pat. No. 6,600,175, U.S. Patent Application Publication No. 2009/0184616, and U.S. Patent Application Publication No. 2012/0306355, which are incorporated by reference. Other materials, such as light scattering elements (e.g., particles) and/or index matching materials, may be associated with a lumiphoric material-containing element or surface. One or more lumiphoric materials useable in devices as described herein may be down-converting or up-converting, or can include a combination of both types.

Lighting devices and methods as disclosed herein may include have multiple solid state emitters (e.g., LEDs) of the same or different dominant colors, or of the same or different peak wavelengths.

In certain embodiments, at least one lumiphoric material may be spatially segregated from and arranged to receive emissions from at least one electrically activated solid state emitter, with such spatial separation reducing thermal coupling between a solid state emitter and lumiphoric material. In certain embodiments, a spatially segregated lumiphor may be arranged to fully cover one or more electrically activated emitters of a lighting device. In certain embodiments, a spatially segregated lumiphor may be arranged to cover only a portion or subset of one or more emitters electrically activated emitters.

In embodiments, one or more lumiphors may be disposed remotely from (i.e., spatially segregated from) at least one solid state emitter, with such spatial separation reducing thermal coupling between a solid state emitter and lumiphoric material. At least one lumiphor may be spatially separated from each solid state emitter, and/or at least one other lumiphor, by a gap or void. Spatial separation between at least one lumiphor and at least one other lumiphor and/or at least one solid state emitter in various embodiments may be at least about 0.5 mm, at least 1 mm, at least about 2 mm, at least about 5 mm, or at least about 10 mm. In certain embodiments, at least one lumiphor may be insubstantially thermally coupled to a solid state emitter, such that conductive heating from a solid state emitter to the lumiphor is minimized. Reducing conductive thermal coupling between a lumiphor and an electrically activated solid state emitter (e.g., LED) may extend the operative life of the lumiphor, reduce undesirable deterioration (e.g., yellowing or darkening) of any binder material, and reduce spectral shift with respect to variations in emitter surface temperature.

In certain embodiments, a lumiphor may be arranged with a substantially constant thickness and/or concentration relative to different electrically activated emitters. In certain embodiments, a lumiphor may be arranged with substantially different thickness and/or concentration relative to different emitters.

A lumiphor that is spatially segregated from one or more electrically activated emitters may have associated light scattering particles or elements, which may be arranged with substantially constant thickness and/or concentration relative to electrically activated emitters of different colors, or may be intentionally arranged with substantially different thickness and/or concentration relative to different electrically activated emitters. Multiple lumiphors (e.g., lumiphors of different compositions) may be applied with different concentrations or thicknesses relative to different electrically activated emitters. In one embodiment, lumiphor composition, thickness and/or concentration may vary relative to multiple electrically activated emitters, while scattering material thickness and/or concentration may differently vary relative to the same multiple electrically activated emitters. In one embodiment, at least one lumiphor material and/or scattering material may be applied to an associated support surface (optionally including an optical element such as a dichroic filter) by patterning, such may be aided by one or more masks.

Various substrates may be used as mounting elements on which, in which, or over which multiple solid state light emitters (e.g., emitter chips) may be arranged or supported (e.g., mounted). Exemplary substrates include printed circuit boards (including but not limited to metal core printed circuit boards, flexible circuit boards, dielectric laminates, and the like) having electrical traces arranged on one or multiple surfaces thereof. A substrate, mounting plate, or other support element may include a printed circuit board (PCB), a metal core printed circuit board (MCPCB), a flexible printed circuit board, a dielectric laminate (e.g., FR-4 boards as known in the art) or any suitable substrate for mounting LED chips and/or LED packages In certain embodiments, at least a portion of a substrate may include a dielectric material to provide desired electrical isolation between electrical traces or components of multiple LED sets. In certain embodiments, a substrate can comprise ceramic such as alumina, aluminum nitride, silicon carbide, or a polymeric material such as polyimide, polyester, etc. In certain embodiments, substrate can comprise a flexible circuit board or a circuit board with plastically deformable portions to allow the substrate to take a non-planar (e.g., bent) or curved shape allowing for directional light emission with LED chips of one or more LED components also being arranged in a non-planar manner.

In certain embodiments, one or more LED components can include one or more “chip-on-board” (COB) LED chips and/or packaged LED chips that can be electrically coupled or connected in series or parallel with one another and mounted on a portion of a substrate. In certain embodiments, COB LED chips can be mounted directly on portions of substrate without the need for additional packaging.

Certain embodiments may involve use of solid state emitter packages. A solid state emitter package may include at least one solid state emitter chip (more preferably multiple solid state emitter chips) that is enclosed with packaging elements to provide environmental protection, mechanical protection, color selection, and/or light focusing utility, as well as electrical leads, contacts, and/or traces enabling electrical connection to an external circuit. One or more emitter chips may be arranged to stimulate one or more lumiphoric materials, which may be coated on, arranged over, or otherwise disposed in light receiving relationship to one or more solid state emitters. A lens and/or encapsulant material, optionally including lumiphoric material, may be disposed over solid state emitters, lumiphoric materials, and/or lumiphor-containing layers in a solid state emitter package.

In certain embodiments, a light emitting apparatus as disclosed herein (whether or not including one or more LED packages) may include at least one of the following items arranged to receive light from multiple LED components: a single lens; a single optical element; and a single reflector. In certain embodiments, a light emitting apparatus including multiple LED components, packages, or groups may include at least one of the following items arranged to receive light from multiple LEDs: multiple lenses; multiple optical elements; and multiple reflectors. Examples of optical elements include, but are not limited to elements arranged to affect light mixing, focusing, collimation, dispersion, and/or beam shaping.

In certain embodiments, lighting devices or light emitting apparatuses as described herein may include at least one LED including emissions with a peak wavelength in the visible range. Multiple LEDs may be provided, and such LEDs may be controlled together or independently. In certain embodiments, at least two independently controlled (e.g., blue, cyan, or green) LEDs may be provided in a single LED component and arranged to stimulate emissions of lumiphors (e.g., yellow green, orange, and/or red), which may comprise the same or different materials in the same or different amounts or concentrations relative to the LEDs. In certain embodiments, multiple electrically activated (e.g., solid state) emitters may be provided, with groups of emitters being separately controllable relative to one another. In certain embodiments, one or more groups of solid state emitters as described herein may include at least a first LED chip comprising a first LED peak wavelength, and include at least a second LED chip comprising a second LED peak wavelength that differs from the first LED peak wavelength by at least 20 nm, or by at least 30 nm (preferably, but not necessarily, in the visible range). In certain embodiments, at least one LED having a peak wavelength in the blue range is arranged to stimulate emissions of at least one lumiphor having a peak wavelength in the yellow range.

The expression “peak emission wavelength” as used herein, means (1) in the case of a solid state light emitter, to the peak wavelength of light that the solid state light emitter emits if it is illuminated, and (2) in the case of a lumiphoric material, the peak wavelength of light that the lumiphoric material emits if it is excited.

The expression “peak excitation wavelength” as used herein means the wavelength of light that stimulates greatest lumiphor emissions.

In certain embodiments, light emitting apparatuses as disclosed herein may be used as described in U.S. Pat. No. 7,213,940, which is hereby incorporated by reference as if set forth fully herein. In certain embodiments, a combination of light (aggregated emissions) exiting a lighting emitting apparatus including multiple LED components as disclosed herein, may, in an absence of any additional light, produce a mixture of light having x, y color coordinates within an area on a 1931 CIE Chromaticity Diagram defined by points having coordinates (0.32, 0.40), (0.36, 0.48), (0.43, 0.45), (0.42, 0.42), (0.36, 0.38). In certain embodiments, combined emissions from a lighting emitting apparatus as disclosed herein may embody at least one of (a) a color rendering index (CRI Ra) value of at least 85, and (b) a color quality scale (CQS) value of at least 85.

Some embodiments of the present invention may use solid state emitters, emitter packages, fixtures, luminescent materials/elements, power supply elements, control elements, and/or methods such as described in U.S. Pat. Nos. 7,564,180; 7,456,499; 7,213,940; 7,095,056; 6,958,497; 6,853,010; 6,791,119; 6,600,175, 6,201,262; 6,187,606; 6,120,600; 5,912,477; 5,739,554; 5,631,190; 5,604,135; 5,523,589; 5,416,342; 5,393,993; 5,359,345; 5,338,944; 5,210,051; 5,027,168; 5,027,168; 4,966,862, and/or 4,918,497, and U.S. Patent Application Publication Nos. 2009/0184616; 2009/0080185; 2009/0050908; 2009/0050907; 2008/0308825; 2008/0198112; 2008/0179611, 2008/0173884, 2008/0121921; 2008/0012036; 2007/0253209; 2007/0223219; 2007/0170447; 2007/0158668; 2007/0139923, and/or 2006/0221272; with the disclosures of the foregoing patents and published patent applications being hereby incorporated by reference as if set forth fully herein.

The expressions “lighting device” and “light emitting apparatus”, as used herein, are not limited, except that they are capable of emitting light. That is, a lighting device or light emitting apparatus can be a device which illuminates an area or volume, e.g., a structure, a swimming pool or spa, a room, a warehouse, an indicator, a road, a parking lot, a vehicle, signage, e.g., road signs, a billboard, a ship, a toy, a mirror, a vessel, an electronic device, a boat, an aircraft, a stadium, a computer, a remote audio device, a remote video device, a cell phone, a tree, a window, an LCD display, a cave, a tunnel, a yard, a lamppost, or a device or array of devices that illuminate an enclosure, or a device that is used for edge or back-lighting, light bulbs, bulb replacements, outdoor lighting, street lighting, security lighting, exterior residential lighting (wall mounts, post/column mounts), ceiling fixtures/wall sconces, under cabinet lighting, lamps (floor and/or table and/or desk), landscape lighting, track lighting, task lighting, specialty lighting, ceiling fan lighting, archival/art display lighting, high vibration/impact lighting-work lights, etc., mirrors/vanity lighting, or any other light emitting devices. In certain embodiments, lighting devices or light emitting apparatuses as disclosed herein may be self-ballasted.

In certain embodiments, a lumiphoric material and at least one electrically activated solid state light emitter may be selected for use with one another to provide reduced luminous flux drop of aggregated light emissions of a lighting device at least one elevated temperature of the at least one solid state light emitter within a predetermined range (e.g., a range from 65° C. to 150° C., from 85° C. to 150° C., from 85° C. to 125° C., or any other desired range).

In certain embodiments, at least one electrically activated solid state light emitter (e.g., a LED) includes a nominal peak emission wavelength at a solid state emitter temperature of 25° C., and the peak excitation wavelength of the lumiphoric material exceeds the nominal peak emission wavelength by a desired threshold (e.g., preferably at least 15 nm, at least 20 nm, at least 25 nm, or some other threshold).

In certain embodiments, a solid state lighting device may include a lumiphoric material (e.g., one or more lumiphoric materials) arranged to receive and be excited by light emissions of at least one electrically activated solid state light emitter. The lumiphoric material includes a peak excitation wavelength. In certain embodiments, at least one electrically activated solid state light emitter (e.g., a LED) includes a nominal peak emission wavelength at a solid state emitter temperature of 25° C., and the peak excitation wavelength of the lumiphoric material exceeds the nominal peak emission wavelength by a desired threshold (e.g., preferably at least 15 nm, at least 20 nm, at least 25 nm, or some other threshold).

In certain embodiments, at least one electrically activated solid state light emitter (e.g., a LED) includes a nominal peak emission wavelength in a range of from 428 nm to 440 nm, or from 432 nm to 440 nm, or from 428 nm to 438 nm, or from 434 nm to 438 nm, or in a visible range at or below 440 nm, when the solid state emitter is at a temperature of 25° C.

In certain embodiments, multiple electrically activated solid state light emitters (e.g., multiple LEDs) may be arranged to excite one or multiple lumiphoric materials. In certain embodiments, a lumiphoric material may include one or more phosphors. In certain embodiments, one or more lumiphoric materials may be arranged to emit light of green, yellow, orange, red, or other dominant colors.

In certain embodiments, at least one lumiphoric material may include a peak emission wavelength in a range of from 540 nm to 572 nm, or in a range of from 550 nm to 562 nm. An example of a lumiphoric material suitable for attaining the foregoing peak emission wavelength ranges is YAG:Ce. In certain embodiments, at least one lumiphoric material may include a peak emission wavelength in a range of from 608 nm to 640 nm, or in a range of from 618 nm to 630 nm. An example of a lumiphoric material suitable for attaining the foregoing peak emission wavelength ranges is SrₓCa₁₋ₓSiAlN₃:Eu. In certain embodiments, multiple lumiphoric materials may be used and stimulated by one or more electrically activated solid state light emitters.

A drop in luminous flux (also termed luminous flux droop) at elevated temperature operation may be quantified by comparison of luminous flux attained by the same device at a lower reference temperature (e.g., 25° C.). Conventional devices including lumiphoric materials and solid state light emitters have been tested by Applicants and determined to have relative luminous flux drops of from 7-12% at 85° C., from 12-16% at 105° C., from 18-21% at 125° C., and from 26-28% at 150° C., all relative to operation of the same devices at 25° C. In contrast to the foregoing conventional devices, a lighting device including at least one electrically activated emitter and a lumiphoric material according to certain embodiments exhibits at least one of the following characteristics (a) to (d): (a) a luminous flux drop of no greater than 5% when operated at a solid state light emitter temperature of 85° C. relative to operation at a solid state light emitter temperature of 25° C., (b) a luminous flux drop of no greater than 8% at a solid state light emitter temperature of 105° C. relative to operation at a solid state light emitter temperature of 25° C., (c) a luminous flux drop of no greater than 12% at a solid state light emitter temperature of 125° C. relative to operation at a solid state light emitter temperature of 25° C., and (d) a luminous flux drop of no greater than 17% at a solid state light emitter temperature 150° C. relative to operation at a solid state light emitter temperature of 25° C. In certain embodiments, a solid state lighting device includes two, three, or all four of characteristics (a) to (d).

In certain embodiments, a solid state lighting device includes a lumiphoric material arranged to receive and be excited by light emissions of at least one electrically activated solid state light emitter, wherein the at least one electrically activated solid state light emitter is arranged to emit light in a blue wavelength range, the lumiphoric material is arranged to emit light in a yellow wavelength range, and the solid state lighting device exhibits at least one (or more preferably at least two, at least two, or all four) of the foregoing characteristics (a) to (d).

In certain embodiments, a solid state lighting device comprising a lumiphoric material having a peak emission wavelength in a yellow range arranged to receive and be excited by light emissions of at least one electrically activated solid state light emitter having a peak wavelength in a range of from 428 nm to 440 nm (or in certain embodiments from 428 nm to 38 nm, from 434 nm to 438 nm, or any other range as disclosed herein) at a solid state light emitter temperature of 25° C., wherein the lumiphoric material comprises a peak excitation wavelength that exceeds the peak emission wavelength of the at least one electrically activated solid state light emitter by at least 20 nm (or by at least 25 nm, or by at least 15 nm in certain embodiments).

In certain embodiments, a solid state lighting device includes a nominal peak emission wavelength in a range of from 428 nm to 440 nm (or from 432 nm to 440 nm, or from 428 nm to 438 nm, or from 434 nm to 438 nm, or in a visible wavelength range of no greater than 440 nm) at a LED temperature of 25° C., and a lumiphoric material arranged to receive and be excited by light emissions of the LED, wherein the lumiphoric material includes a peak excitation wavelength, and the solid state lighting device comprises at least one of the following features (a) and (b): (a) the peak excitation wavelength of the lumiphoric material exceeds the nominal peak emission wavelength by at least 15 nm (or by at least 20 nm, or by at least 25 nm in certain embodiments), and (b) the solid state lighting device is devoid of any lumiphoric material comprising a peak excitation wavelength within 15 nm (or within 20 nm, or within 25 nm in certain embodiments) of the nominal peak emission wavelength. In certain embodiments, a solid state lighting device comprises both features (a) and (b). In certain embodiments, at least one lumiphoric material comprises a peak emission wavelength in a range of from 540 nm to 572 nm, and/or in a range of from 608 nm to 640 nm.

In certain embodiments, a solid state lighting device includes a lumiphoric material having a peak emission wavelength in a yellow range arranged to receive and be excited by light emissions of at least one electrically activated solid state light emitter having a peak emission wavelength in a blue range, wherein: aggregated emissions of the at least one electrically activated solid state light emitter and the lumiphoric material comprise (a) an high temperature luminous flux value when the at least one electrically activated solid state light emitter is operated at 85° C., and (b) a low temperature luminous flux value when the at least one electrically activated solid state light emitter is operated at 25° C., wherein relative luminous flux comprises a ratio of the high temperature luminous flux value to the low temperature luminous flux value; emissions of the at least one electrically activated solid state light emitter comprise (c) a high temperature radiant flux value when the at least one electrically activated solid state light emitter is operated at 85° C., and (d) a low temperature radiant flux value when the at least one electrically activated solid state light emitter is operated at 25° C., wherein relative radiant flux comprises a ratio of the high temperature radiant flux value to the low temperature radiant flux value; and a ratio of relative luminous flux to relative radiant flux is greater than or equal to 0.98.

In certain embodiments, a solid state lighting device may include first and second components each including an electrically activated solid state light emitter (e.g., LED) and a lumiphoric material selected for use with one another as disclosed herein.

In certain embodiments, lumiphoric material is spatially segregated from each electrically activated solid state light emitter of the at least one electrically activated solid state light emitter.

In various embodiments described herein, an electrically activated solid state light emitter (e.g., an LED) may include an improved epitaxial structure (e.g., a III-nitride epitaxial structure) arranged to further reduce luminous flux droop at elevated temperature. Such improvements include one or more of the following: (a) increasing thickness of an unintentionally doped layer arranged between a substrate and a silicon-doped layer underlying an active layer, (b) increasing thickness of a cap layer over the active region; (c) doping of at least a portion of a cap layer with Mg, Zn, and/or another p-type dopant, and (d) increasing thickness of a buffer layer arranged over a substrate, and (e) increasing thickness of a Si-doped GaN layer underlying the active region.

Regarding improvement (a), in certain embodiments, the unintentionally doped layer is increased by at least about 80%, at least about 120%, at least about 160%, or at least about 200% relative to a conventional unintentionally doped layer (for example, from a conventional thickness of about 5400 Angstroms to a thickness of at least about 10,000 Angstroms or at least about 15,000 Angstroms). Increasing thickness of the unintentionally doped layer below the silicon-doped layer decreases defect density in the active region, which reduces the probability of non-radiative recombination at defects in the crystal. Since the probability of a non-radiative recombination event increases with temperature, presence of lower defect density is beneficial at higher emitter operating temperature to reduce luminous flux droop.

Regarding improvement (b), in certain embodiments, the thickness of a cap (or electron blocking) layer over the active region is increased by at least about 25%, more preferably by at least about 50%, relative to a conventional cap layer (for example, from a conventional thickness of about 240 Angstroms to at least about 300 Angstroms or at least about 360 Angstroms). This increase in cap or electron blocking layer thickness enhances efficacy of electron blocking, which reduces electron overshoot. Since electron overshoot increases at higher temperature, presence of a thicker electron blocking layer improves thermal luminous flux droop performance.

Consistent with the foregoing improvements (a) and (b), in various embodiments, at least one electrically activated solid state light emitter of a lighting device disclosed herein comprises an epitaxial structure including a substrate, a buffer layer, an unintentionally doped III-nitride layer overlying the buffer layer, a Si-doped III-nitride layer overlying the unintentionally doped III-nitride layer, a III-nitride active region overlying the Si-doped III-nitride layer, an III-nitride cap layer overlying the III-nitride active region, and at least one p-doped III-nitride overlying the III-nitride cap layer, wherein the unintentionally doped III-nitride layer has a thickness of at least 10,000 Angstroms (more preferably at least 15,000 Angstroms), and wherein the cap layer has a thickness of at least 300 Angstroms (more preferably at least 360 Angstroms). In certain embodiments, the unintentionally doped III-nitride layer comprises unintentionally doped GaN, the Si-doped III-nitride layer comprises Si-doped GaN, the III-nitride cap layer comprises InAlGaN, and the at least one p-doped III-nitride layer comprises (i) a p-doped AlGaN layer and (ii) a p-doped GaN layer. The substrate may include silicon carbide in certain embodiments.

Regarding improvement (c), doping of at least a portion of a cap layer with Mg, Zn, and/or another p-type dopant in order to increase the number of holes available to enhance performance of an adjacent active region.

Regarding improvements (d) and (e), increasing thickness of a buffer layer arranged over a substrate according to improvement (d) and increasing thickness of a Si-doped GaN layer underlying the active region according to improvement (e) may result in decreased defect density in the active region, thereby reducing the probability of non-radiative recombination at defects in the crystal.

Various illustrative features are described below in connection with the accompanying figures.

FIGS. 2, 3, and 4 show various features of an exemplary light emitting diode (LED) package 30 that may be used to operate at least one LED (or other electrically activated solid state light emitter) and stimulate emissions of a lumiphoric material according to embodiments disclosed herein. The package 30 generally includes a substrate/submount (“submount”) 32 that can hold one or more LEDs emitting the same or different colors. In FIGS. 2-4, a single LED 34 is illustrated as being mounted on the submount 32. The LED 34 can have many different semiconductor layers arranged in different ways. LED structures, their fabrication, and their operation are generally known in the art and only briefly discussed herein. The layers of the LED 34 can be fabricated using known processes with a suitable process being fabrication using metal organic chemical vapor deposition (MOCVD). The layers of the LEDs 34 generally include an active layer/region sandwiched between first and second oppositely doped epitaxial layers which are formed successively over a growth substrate. LEDs can be formed on a wafer and then singulated for mounting in a package. It is understood that the growth substrate can remain as part of the final singulated LED or the growth substrate can be fully or partially removed. In embodiments where the growth substrate remains, it can be shaped or textured to enhance light extraction. The growth substrate can be made of various materials such as sapphire, silicon carbide, AlN, or GaN.

It is also understood that additional layers and elements can also be included in the LED 34, including but not limited to buffer, nucleation, contact and current spreading layers as well as light extraction layers and elements. It is also understood that the oppositely doped layers can comprise multiple layers and sub-layers, as well as super lattice structures and interlayers. The active region can comprise single quantum well (SQW), multiple quantum well (MQW), double heterostructure or super lattice structures. The active region and doped layers may be fabricated from different material systems, with preferred material systems being Group-III nitride based material systems. Group-III nitrides refer to those semiconductor compounds formed between nitrogen and the elements in Group III of the Periodic Table, usually aluminum (Al), gallium (Ga), and indium (In). The term also refers to ternary and quaternary compounds such as aluminum gallium nitride (AlGaN) and aluminum indium gallium nitride (AlInGaN). In certain embodiments, the doped layers may include gallium nitride (GaN) and the active region may include InGaN. In other embodiments, the doped layers may include AlGaN, aluminum gallium arsenide (AlGaAs) or aluminum gallium indium arsenide phosphide (AlGaInAsP).

The LED 34 may include a conductive current spreading structure 36 on its top surface, and one or more contacts 38 accessible at its top surface for wire bonding. The spreading structure 36 and contact can both be made of a conductive material (e.g., Au, Cu, Ni, In, Al, Ag or combinations thereof, conducting oxides and transparent conducting oxides). The current spreading structure 36 generally includes conductive fingers 37 arranged in a grid on the LED 34 with the fingers spaced to enhance current spreading from the contacts 38 to the top surface of the LED.

The LED can be coated or otherwise overlaid with one or more lumiphors (e.g., phosphors) arranged to absorb at least a portion of the LED emissions and responsively re-emit light of a different wavelength of light, with aggregate emissions from the lighting device preferably including a combination of LED emissions and lumiphor emissions. The LED can be coated using many different methods and with many different lumiphoric materials, with suitable methods and materials being described in U.S. Patent Application Publication Nos. 20080173884 and 20080179611, both entitled “Wafer Level Phosphor Coating Method and Devices Fabricated Utilizing Method”, and both of which are incorporated herein by reference. Alternatively the LEDs can be coated using other methods such an electrophoretic deposition (EPD), with a suitable EPD method described in U.S. Patent Application Publication No. 20070158668 entitled “Close Loop Electrophoretic Deposition of Semiconductor Devices”, which is also incorporated herein by reference. It is understood that LED packages as described can also have multiple LEDs of different colors, one or more of which may be white emitting by combining a LED with one or more lumiphors.

The submount 32 can be formed of various different materials with a preferred material being electrically insulating. Suitable materials include, but are not limited to ceramic materials such as aluminum oxide, aluminum nitride or organic insulators like polyimide and polyphthalamide. In other embodiments the submount 32 may include a printed circuit board (PCB), sapphire, silicon, or any other suitable material, such as T-Clad thermal clad insulated substrate material (available from The Bergquist Company of Chanhassen, Minn.). PCB embodiments of various PCB types can be used, such as standard FR-4 PCB, metal core PCB, or any other type of PCB. A submount preferably has low thermal resistance to promote dissipation of heat into an ambient environment.

An attach pad 42 and contact pads 44, 46 are arranged over the submount 32, and may comprise metals (e.g., plated or deposited copper) or other conductive materials. Alignment features such as square cut-outs 31 may be provided along a top surface of the attach pad 42 to aid in aligning the LED. A gap 48 is provided between the second pad 46 and the attach pad 42 down to the surface of the submount 32 to provide electrical isolation between the attach pad 42 and second pad 46. In certain embodiments, an electrical signal can be applied to the package 30 by providing external electrical contact to the first and second bond pads 44, 46 such as by solder contacts or other conductive paths to a PCB. A solder mask 58 can be included on a top surface 40 of the submount 32, at least partially covering the attach pad 42 and contact pads 44, 46, and at least partially covering the gap 48. The solder mask 58 arranged to protect these features during subsequent processing steps and in particular during mounting of the LED 34 to the attach pad 42 and wire bonding (i.e., when joining wirebonds 65 to LED chip contacts 38). The solder mask 58 includes an opening for the electrostatic discharge (ESD) diode 62, and an ESD wire bond 64 is included between the second contact pad 46 at the solder mask opening and the ESD diode 62.

The package 30 as shown is arranged for surface mounting. First and second surface mount pads 50, 52 are formed on a back surface 54 of the submount 32 at least partially in alignment with the first and second contact pads 44, 46. Electrically conductive vias 56 are formed through the submount 32 between the first mounting pad 50 and the first contact pad 44, such that a signal applied to the first mounting pad 50 is conducted to first contact pad 44; similarly, conductive vias 56 are formed between the second mounting pad 52 and second contact pad to conduct an electrical signal therebetween. The first and second mounting pads 50, 52 allow for surface mounting of the LED package 30 with the electrical signal to be applied to the LED 34 applied across the first and second mounting pads 50, 52. The back surface of the submount 32 may also include a metalized area 66 below the LED 34 and between the mounting pads 50, 52 to promote thermal conduction and heat dissipation.

As best shown in FIG. 4, an optical element or lens 70 is formed on the top surface 40 of the submount 32, over the LED 34, to provide both environmental and/or mechanical protection. The lens 70 can be in different locations on the top surface 40 with the lens located as shown with at approximately the center of the submount 32, with the LED 34 at approximately the center of the lens base. In some embodiments the lens can be formed in direct contact with the LED 34 and a top surface 40 of the submount. In other embodiments, an intervening material or layer between the LED 34 and top surface 40 may be provided.

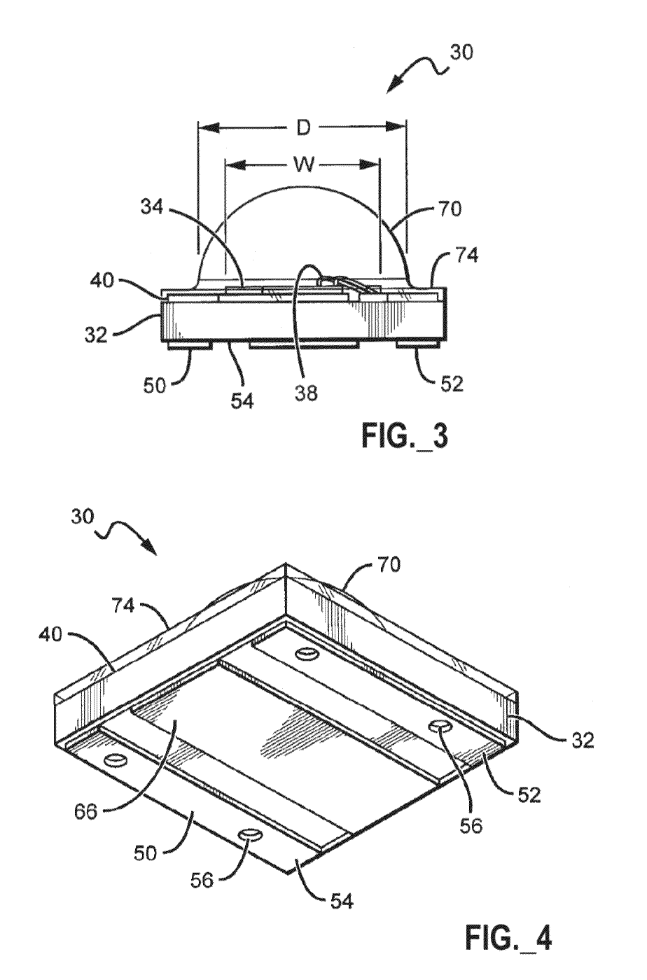

A lens 70 can be molded using different molding techniques such as those described in U.S. Patent Application Publication No. 20090108281 entitled “Light Emitting Diode Package and Method for Fabricating Same”, which is incorporated herein by reference. The lens can be many different shapes depending on the desired shape of the light output. One suitable shape as shown is hemispheric, with some examples of alternative shapes being ellipsoid bullet, flat, hex-shaped, rectangular, square, and square with light extracting recesses. Various different materials can be used for the lens such as silicones, plastics, epoxies or glass, with such materials preferably being compatible with a molding process. Silicone is suitable for molding, provides suitable optical transmission properties, can withstand subsequent reflow processes, and does not significantly degrade over time. In certain embodiments, the lens 70 may be textured to improve light extraction and/or may incorporate or include materials such as lumiphors (e.g., phosphors) or scattering particles. In certain embodiments, the lens 70 can comprise two portions: a flat portion 70a and a domed portion 70b, with the flat portion 70a being disposed over the LED 34, and with the domed portion 70b positioned on the flat portion 70a. These lens portions 70a, 70b can be made of the same material or different materials relative to one another. In certain embodiments, a ratio of the width of the light emitter chip (W) to the width of the lens (D) (with reference to FIG. 3) in a given direction is 0.5 or greater.

The LED package 30 may optionally include a protective layer 74 covering the top surface 40 of the submount between the lens 70 and the edge of the submount 32. Such layer 74 may provide additional protection to elements on the top surface to reduce damage and contamination during processing steps and use. In certain embodiments, the protective layer 74 can be formed during formation of the lens 70 and can be formed of or include the same material as the lens 70.

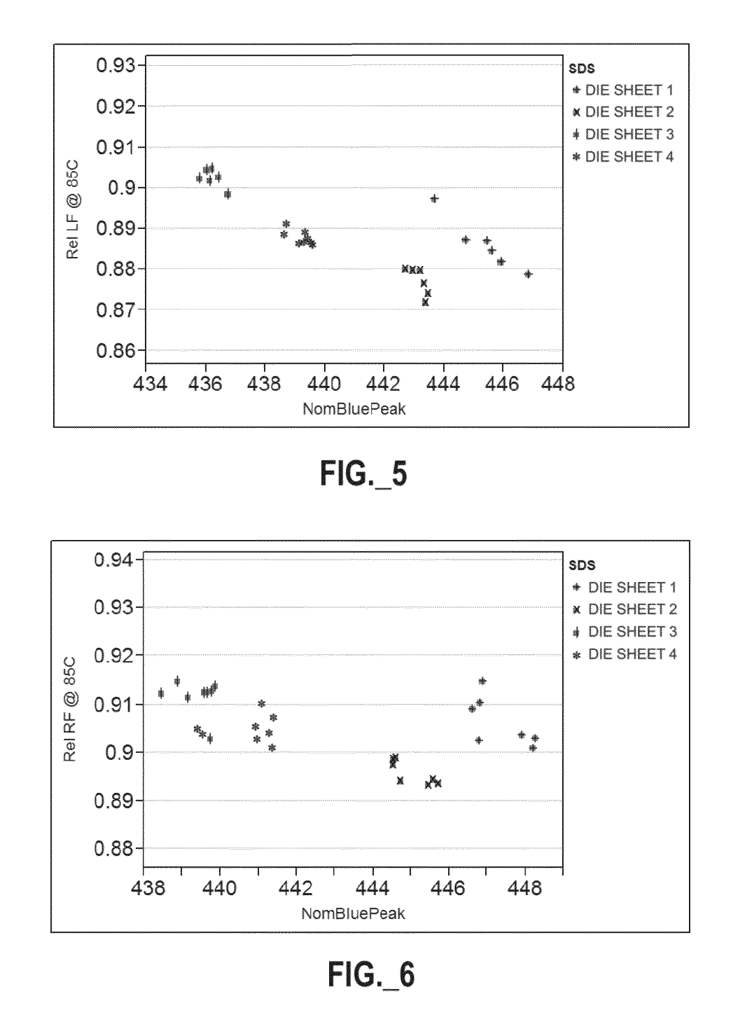

Referring to FIGS. 5-8, multiple LED packages (Cree type XPG) consistent with the type described in connection with FIGS. 2-4 were fabricated to study the efficacy of matching lumiphors and solid state emitters as described herein for reducing luminous flux droop at elevated temperatures. Four blue LED wafers with a range of peak emission wavelengths (approximately 436 nm to 446 nm) were produced and singulated to each form multiple LED chips, with resulting individual LED chips coated with YAG:Ce phosphor added to such packages.

Tests were performed on the white light-emitting packages to determine luminous flux at 25° C. and at 85° C. FIG. 5 is a plot of relative luminous flux (Rel LF) versus nominal blue LED peak wavelength for white light emissions of emitter packages including the four different blue LED peak emission wavelengths, and with each package including a blue LED arranged to stimulate a yellow phosphor. Rel LF in such figure represents a ratio of luminous flux at 85° C. to luminous flux at 25° C.—in other words, white luminous flux hot/cold ratio. The greatest Rel LF was obtained from packages including blue LEDs with 436 nm nominal peak wavelengths, followed by packages including blue LEDs with ˜439 nm nominal peak wavelengths, followed by packages including blue LEDs with ˜446 nm nominal peak wavelengths, followed by packages including blue LEDs with ˜443 nm nominal peak wavelengths.

Following testing of the packages to determine relative luminous flux (as illustrated in FIG. 5), the yellow phosphor was stripped from the LED die on each package to yield devices emitting blue light only. Tests were performed on the blue light-emitting packages to determine radiant flux at 25° C. and at 85° C. FIG. 6 is a plot of relative radiant flux (Rel RF) versus nominal blue LED peak wavelength for the resulting packages. The greatest Rel Rf was obtained from packages including blue LEDs with ˜439 nm nominal peak wavelengths, and the least Rel Rf was obtained from packages including blue LEDs with ˜443 nm nominal peak wavelengths.

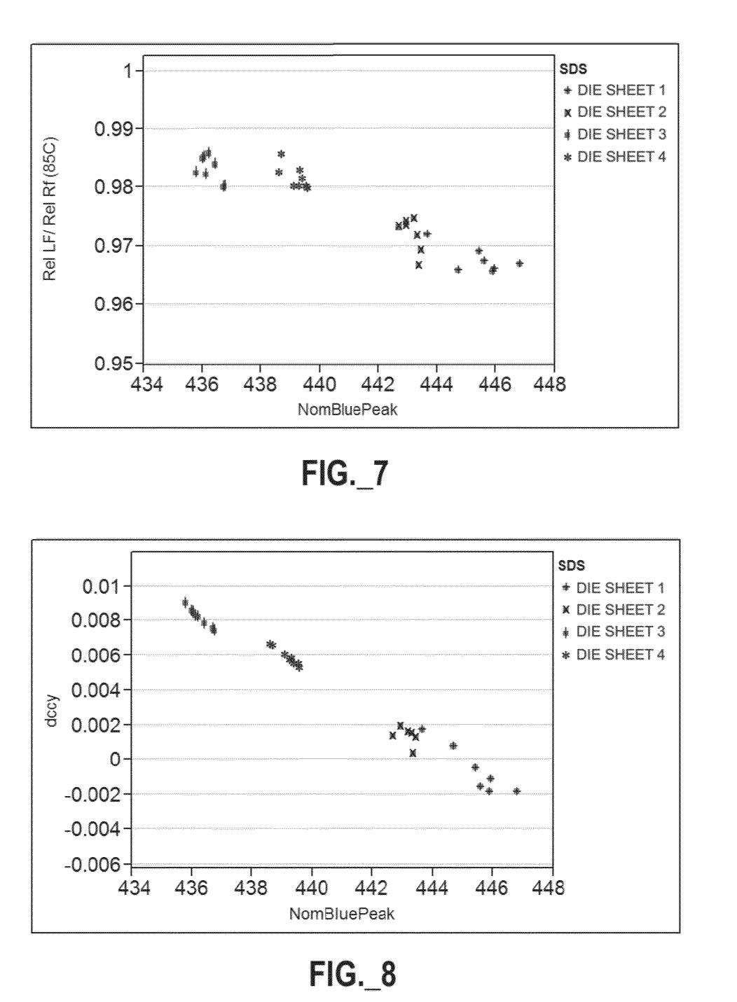

FIG. 7 is a plot of relative luminous flux divided by relative radiant flux (Rel LF/Rel RF) versus nominal blue LED peak wavelength obtaining by dividing the Rel LF values of FIG. 5 by the corresponding Rel RF values of FIG. 6 for the emitter packages. The white light luminous flux droop divided by the blue light radiant flux droop is useful to quantify the contribution of the phosphor to the luminous flow droop (i.e., the phosphor-related LF droop). The blue LED with the longest wavelength (approximately 446 nm) had the greatest phosphor-related LF droop (with a Rel LF/Rel Rf value of around 96.5%), whereas the blue LED with the shortest wavelength (approximately 436 nm) had the least phosphor-related LF droop (with a Rel LF/Rel Rf value of around 98.5%), showing that phosphor-related LF droop improves approximately 2% by reducing the blue LED peak wavelength about 10 nm (from a peak emission wavelength of about 446 nm to about 436 nm). In certain embodiments according to the present invention, a lighting device a ratio of relative luminous flux to relative radiant flux is greater than or equal to 0.98—with such ratio not being attainable with conventional devices within the knowledge of Applicants.

FIG. 8 is a plot of color shift (change in ccy) versus nominal blue peak wavelength for the white light-emitting solid state emitter packages tested in connection with FIGS. 5-7. FIG. 8 shows that change in ccy (dccy) becomes more positive at a shorter dominant (blue LED) wavelength.

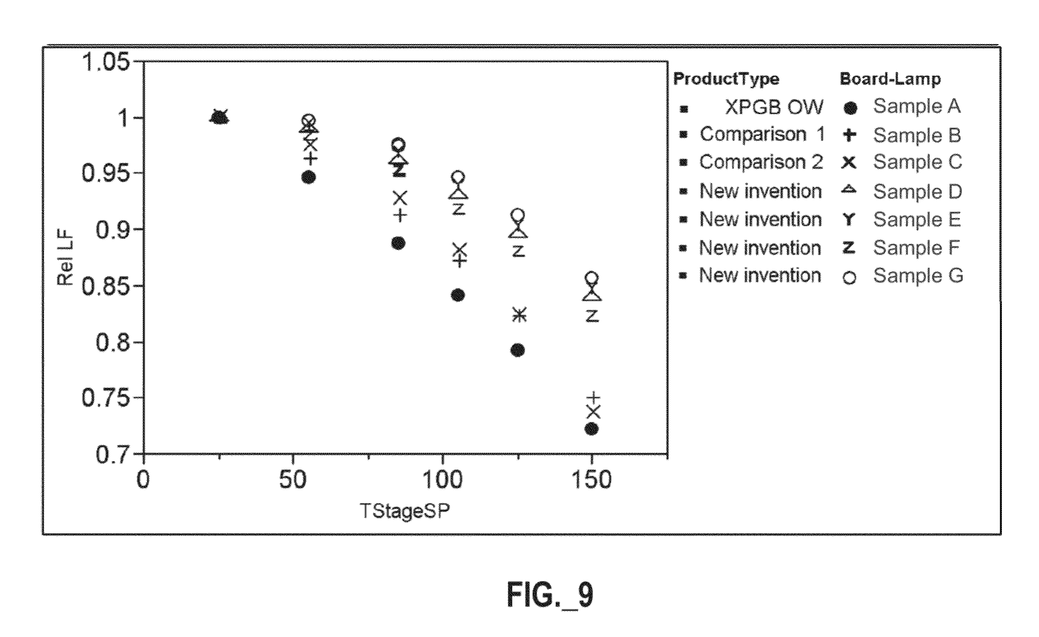

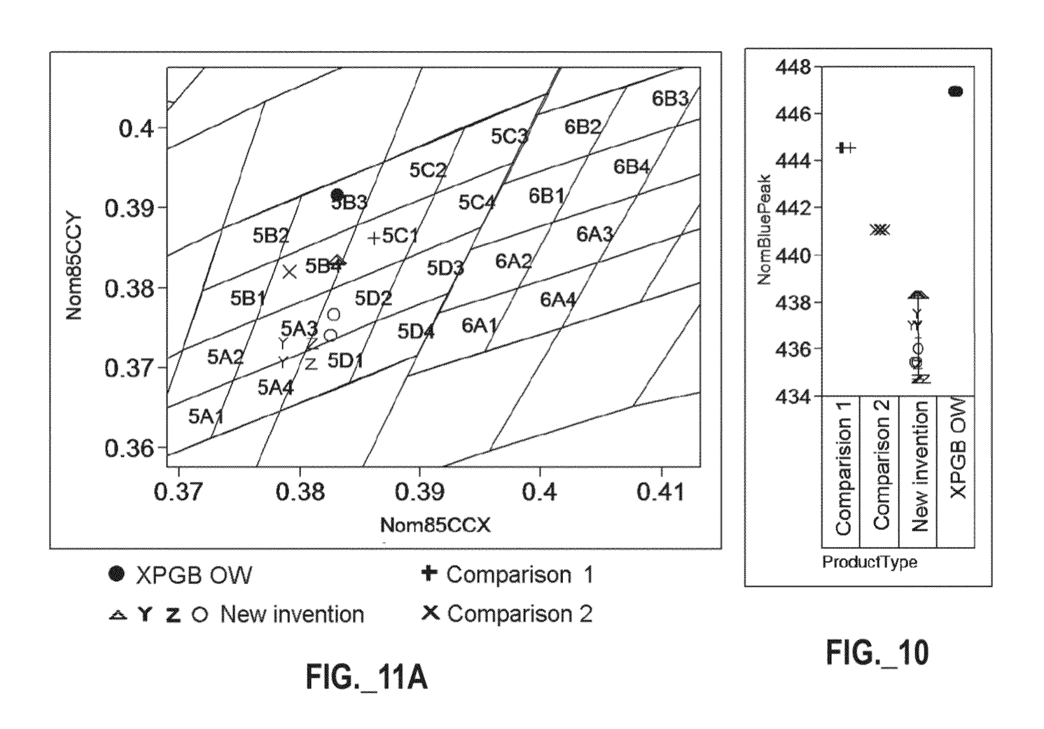

Following the study described in connection with FIGS. 5-8, testing was performed to compare luminous flux droop of blue LED/yellow phosphor devices having shorter nominal blue LED peak emission wavelengths (i.e., from about 434 nm to about 438 nm) relative to conventional blue LED/yellow phosphor devices having longer nominal blue LED peak emission wavelengths (i.e., from 441 nm to 447 nm). Seven board-lamp apparatuses were constructed, yielding seven groups of white light emitters with blue LEDs arranged to stimulate yellow phosphor. The groups of white light emitters included a first comparison emitter (“Comparison 1” including a blue LED obtained from a first third-party manufacturer) having a nominal blue LED peak wavelength of about 444.5 nm, a second comparison emitter (“Comparison 2” including a blue LED obtained from a second third-party manufacturer) having a nominal blue LED peak wavelength of about 441 nm, a third comparison emitter (a Cree XPGB OW having a nominal blue LED peak wavelength of about 447 nm), and four emitters according to embodiments of the present invention having nominal blue LED peak wavelengths from 435 nm to 438.5 nm. Luminous flux (LF) for each white light emitter was tested (with values obtained directly from rel. sphere) while at LED temperature values of 25° C., 60° C., 85° C., 105° C., 125° C., and 150° C. Each LF value obtained at temperatures above 25° C. was divided by the LF value of the corresponding emitter obtained at 25° C. to obtain relative luminous flux (Rel LF). FIG. 10 is a plot of nominal blue peak wavelength (nm) versus category for the emitters of FIG. 9.

As shown in FIG. 9, the comparison emitters tested by Applicants were determined to have relative luminous flux drops of 3-6% at 60° C., from 7-12% at 85° C., from 12-16% at 105° C., from 18-21% at 125° C., and from 26-28% at 150° C., all relative to operation of the same devices at 25° C. In contrast to the foregoing conventional devices, the four emitters according to embodiments of the present invention having nominal blue LED peak wavelengths from 435 nm to 438.5 nm experienced significantly reduced thermal flux droop, with relative luminous flux drops no greater than 2% (i.e., from 1 to 2%) at 60° C., no greater than 5% (i.e., from 3-5% at 85° C.), no greater than 8% (i.e., from 6-8% at 105° C., no greater than 12% (i.e., from 9-12%) at 125° C., and no greater than 17% (i.e., from 14 to 17%) at 150° C. Significant improvement in luminous flux thermal droop for blue LEDs in combination with yellow phosphors by using shorter peak emission wavelength LEDs has therefore been demonstrated.

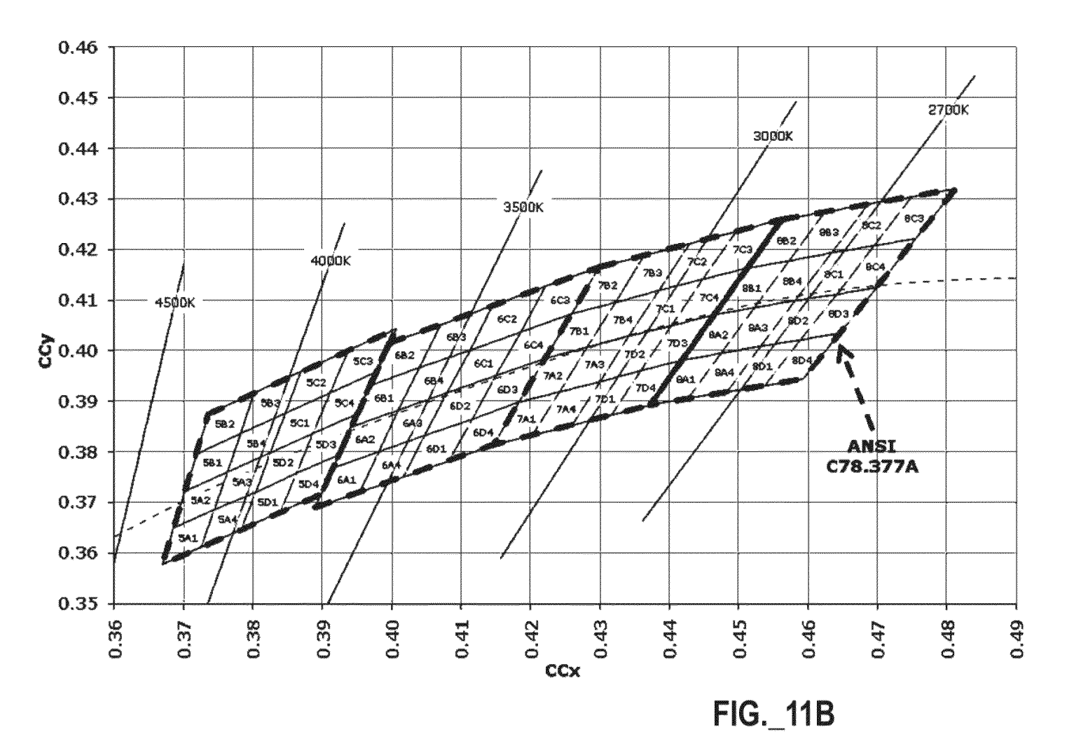

FIG. 11A is a chart including color coordinates ccy versus ccx on a portion of a CIE 1931 x,y Chromaticity Diagram for the white light emitters of FIGS. 9-10, with superimposed identification of Cree bin numbers 5A1 to 6B3 as well as larger (dashed line) bins according to ANSI C78.377A. FIG. 11B is a portion of a CIE 1931 x,y Chromaticity Diagram with superimposed identification of Cree bin numbers 5A1 to 8C3 and color temperature lines, to provide context to the coordinates of the white light emitters plotted in FIG. 11A. FIGS. 11A-11B demonstrate that improved luminous flux thermal droop through use of shorter peak emission wavelength LEDs can be attained with relatively modest alteration of chromaticity.

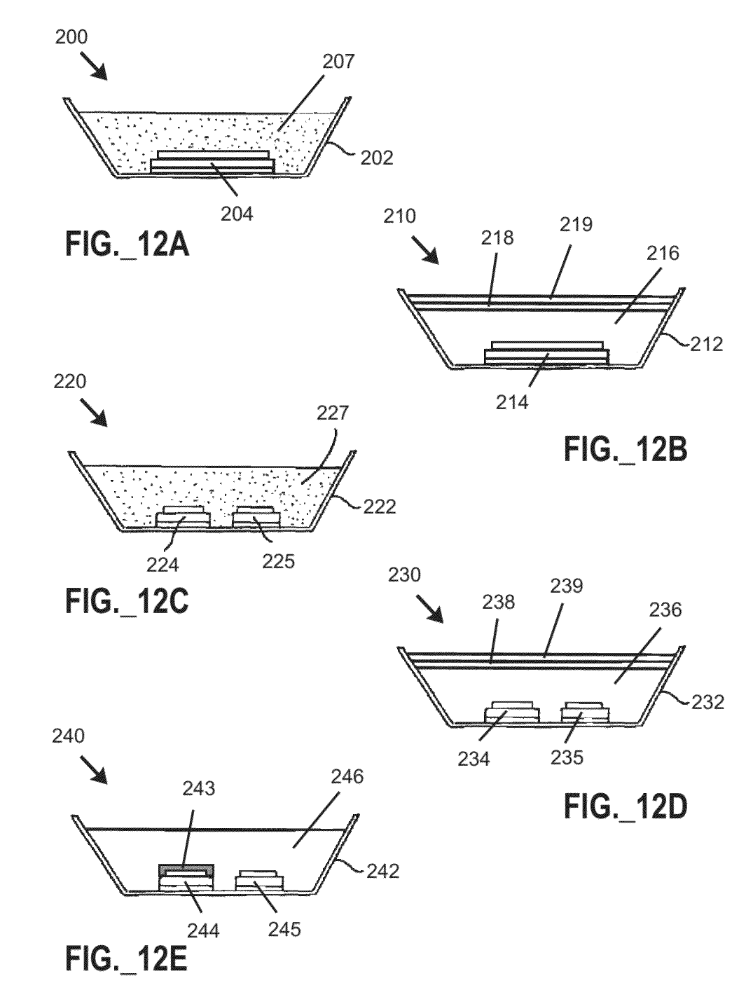

Although a specific solid state emitter device structure was described herein in connection with FIGS. 2-4, it is to be appreciated that electrically activated solid state light emitters and lumiphoric materials may be matched to provide reduced thermal droop characteristics and utilized in solid state lighting devices of any of various types known in the art. Exemplary portions of solid state lighting devices incorporating electrically activated solid state light emitters and lumiphoric materials are illustrated in FIGS. 12A-12E. It is to be appreciated that various structures employed within complete lighting devices (e.g., package leads, leadframes, contacts, wirebonds, bond structures, heat transfer elements, light extracting optics, diffusers, additional reflecting surfaces, power supplies, and the like) have been omitted for clarity of illustration, but one skilled in the art would appreciate that known structures could be incorporated in operative lighting devices including the illustrative portions provided in FIGS. 12A-12E.

The configurations shown in FIGS. 12A-12E may be used in conjunction with any one or more embodiments described herein.

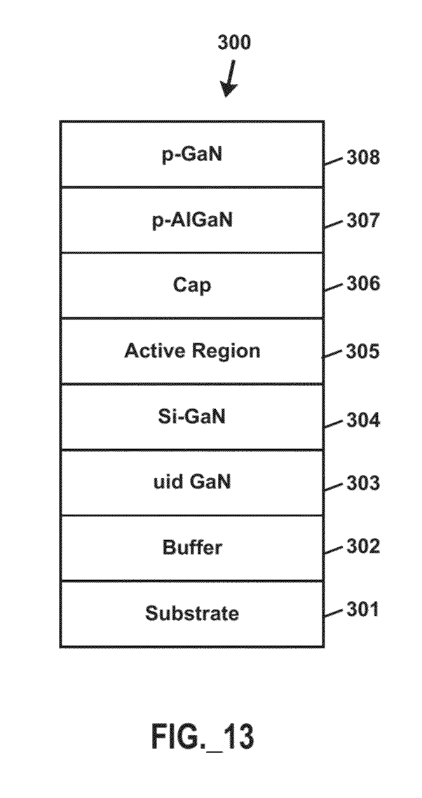

FIG. 12A is a side cross-sectional schematic view of a portion of a solid state lighting device 200 including an electrically activated solid state light emitter (e.g., LED) 204, a reflector cup 202 or other support structure on or over which the LED 204 is mounted, and at least one lumiphor (e.g., phosphor) 207 dispersed in an encapsulant material disposed over the LED 204 and within the reflector cup 202. In certain embodiments, the lumiphor 207 has a peak stimulation wavelength, the LED 204 has a peak emission wavelength under room temperature LED conditions, and the peak stimulation wavelength exceeds the room temperature peak emission wavelength by at least 15 nm (or preferably at least 20 nm). In certain embodiments, the LED may include an epitaxial structure such as described in connection with FIG. 13.

Although FIG. 12A illustrates the at least one lumiphor 207 as being dispersed in an encapsulant material, in various embodiments one or more lumiphors (e.g., phosphors) may be disposed in any suitable conformation to receive emissions from a solid state (e.g., LED) emitter and responsively re-emit light. In certain embodiments, at least one lumiphor may be coated directly on or over a solid state emitter. In certain embodiments, one or more lumiphors may be arranged in separate layers that may be spatially separated from each solid state emitter and/or one another.

FIG. 12B is a side cross-sectional schematic view of a portion of a solid state lighting device 210 including an electrically activated solid state emitter (e.g., LED) 214, a reflector cup 212 or other support structure on or over which the solid state emitter 214 is mounted, and multiple lumiphors (e.g., phosphors) 218, 219 arranged in layers that are spatially segregated from the solid state emitter 214. An encapsulant 216 may be disposed between the solid state emitter 214 and the lumiphors 218, 219; alternatively, at least one void may be arranged between the solid state emitter 214 and the lumiphors 218, 219 to reduce conductive thermal coupling therebetween.

One advantage of utilizing a single solid state emitter (e.g., LED) in conjunction with multiple lumiphors (such as may be implemented in devices according to FIGS. 12A-12B) is that point sources of different colors (such as would be present in a device having multiple LEDs of different colors) are eliminated, thus dispensing with any need for diffusers to promote color mixing. Since a diffuser may be mounted some distance from solid state emitters to provide optimal diffusive effect, elimination of a diffuser permits a resulting solid state lighting device to be substantially thinner than a comparable device including a diffuser. This enhances versatility for device mounting and placement of optics, and also reduces cost and potential unsightliness or volumetric constraints associated with diffusers.

FIG. 12C is a side cross-sectional schematic view of a portion of a solid state lighting device 220 including first and second solid state emitters (e.g., LEDs) 224, 225, a reflector cup 222 or other support structure on or over which the solid state emitters 224, 225 are mounted, and at least one lumiphor (e.g., phosphor) 227 dispersed in an encapsulant material disposed over the solid state emitters 224, 225 and within the reflector cup 222. In certain embodiments, multiple lumiphors 227 may be provided. In one embodiment, one or more lumiphors may be arranged to interact with only a single solid state emitter 224, 225. At least one lumiphor may be disposed in an amount (e.g., thickness, width, etc.) or concentration that varies with respect to position within a solid state lighting device, such embodied in variations of presence, amount or concentration with respect to one or more solid state emitters. For example, at least one lumiphor may be coated over or arranged over one solid state emitter, and not arranged over (or arranged in a different thickness or concentration over) another solid state emitter.

In certain embodiments, a solid state lighting device may include multiple electrically activated solid state emitters (e.g., LEDs) and one or more lumiphors (e.g., phosphors) arranged in one or more layers spatially separated from the solid state emitters. FIG. 12D is a side cross-sectional schematic view of a portion of a solid state lighting device 230 including first and second solid state emitters (e.g., LEDs) 234, 235, a reflector cup 232 or similar support structure on or over which the solid state emitters 234, 235 are mounted, and one or more lumiphors (e.g., phosphors) 238, 239 arranged in layers that are spatially segregated from the solid state emitters 234, 235. An encapsulant 236 or other material may be disposed between the solid state emitters 234, 235 and the lumiphors 238, 239; alternatively, the solid state emitters 234, 235 and lumiphors 238, 239 may be separated by a gap. In one embodiment, the lumiphors 238, 239 may be arranged in alternating layers including at least two non-adjacent layers including lumiphors of substantially same material composition. One advantage of confining different lumiphors to different layers is to avoid undue absorption of emission spectrum of one lumiphor that may overlap with excitation spectrum of another lumiphor (e.g., excitation spectrum of a red phosphor may overlap with emission spectrum of a yellow phosphor) which would result in loss of efficiency). In certain embodiments, presence of a lumiphoric material may be non-uniform (e.g., patterned) within an individual lumiphor layer. In certain embodiments, a lumiphoric material layer may have a thickness that is non-uniform with respect to position.

FIG. 12E is a side cross-sectional schematic view of a portion of a solid state lighting device 240 including first and second electrically activated solid state emitters (LEDs) 244, 245, a reflector cup 242 or other support structure on or over which the LEDs 244, 245 are mounted, and at least one lumiphor 243 arranged to interact only (or primarily only) with a single LED 244. In certain embodiments, the at least one lumiphor 243 may be coated or deposited on or over a first solid state emitter 244 but omitted from the second solid state emitter 245. In certain embodiments, the at least one lumiphor 243 may include a mixture of multiple lumiphors, and/or multiple layers of lumiphors having different material compositions.

Any of the embodiments illustrated or described in connection with FIGS. 12C-12E may be arranged to output aggregated emissions including two, three, or four or more color peaks, depending on the number of solid state emitters and/or lumiphors. In certain embodiments, electrically activated solid state emitters illustrated in FIGS. 12C-12E may have dominant wavelengths that are short wavelength blue, long wavelength blue, cyan, and/or green, although at least one short wavelength blue peak at or below 440 nm is preferably provided. In certain embodiments, solid state emitters of substantially different dominant wavelengths may be provided in the same lighting device; in other embodiments, multiple emitters of the same or substantially the same dominant wavelength may be provided in the same emitter device. In certain embodiments, lumiphors may be arranged to interact with any one or more of the solid state emitters. Although only two electrically activated solid state emitters are illustrated in each of FIGS. 12C-12E, it is to be appreciated that any desirable number of solid state emitters may be provided in a single device, and that such a device may embody at least one of the following features: the solid state emitters are disposed on or over a common submount; the solid state emitters are connected to a single leadframe, the solid state emitters are arranged to emit light for reflection by a single reflector, and the solid state emitters are arranged to emit light for transmission through a single diffuser, filter, or lens.

As noted previously, an electrically activated solid state light emitter (e.g., an LED) may include an improved epitaxial structure (e.g., a III-nitride epitaxial structure) arranged to further reduce luminous flux droop at elevated temperature. Such improvements may include one, some, or all of the following features: (a) increasing thickness of an unintentionally doped layer arranged between a substrate and a silicon-doped layer underlying an active layer, (b) increasing thickness of a cap layer over the active region, (c) doping of at least a portion of a cap layer with Mg, Zn, and/or another p-type dopant, and (d) increasing thickness of a buffer layer arranged over a substrate, and (e) increasing thickness of a Si-doped GaN layer underlying the active region.

FIG. 13 is a side cross-sectional schematic view of an epitaxial structure 300 of a Group-III nitride-based light emitting diode according to certain embodiments of the present invention. FIG. 13 illustrates a substrate 301, a buffer layer 302 overlying the substrate, an unintentionally doped GaN layer 303 overlying the buffer layer, a silicon-doped GaN layer 304 overlying the unintentionally doped GaN layer, a III-nitride active region 305 overlying the silicon-doped GaN layer, an cap (or electron blocking) layer 306 overlying the III-nitride active region, a p-type AlGaN layer 307 overlying the cap layer, and a p-type GaN layer 308 overlying the p-type AlGaN layer. Any one or more of the preceding layers 301-308 may include multiple sublayers having compositions that differ among (or between) respective sublayers. Although the layers 301-308 are illustrated in FIG. 13 as having equal thicknesses, it is to be appreciated the layers 301-308 will have different thicknesses, such that FIG. 13 is schematic only and is not drawn to scale.

The substrate 301 may be any suitable material that is epitaxially compatible with growth of III-nitride layers thereon or thereover. Examples of suitable materials for the substrate 301 include, but are not limited to, silicon carbide, sapphire, and a III-nitride material (e.g., GaN). The buffer layer 302 may include III-nitride material (e.g., GaN) or another a material that is epitaxially compatible with III-nitride material. In certain embodiments, the buffer layer 302 may having a thickness in a range of from 1000 Angstroms to about 4000 Angstroms; in certain embodiments, the buffer layer 302 may have a thickness selected from one of, or in a range between two values of, the following values: 1800 Å, 2000 Å, 2200 Å, 2400 Å, 2600 Å, 2800 Å, 3000 Å, 3200 Å, 3400 Å, or 3600 Å.

In certain embodiments, the unintentionally doped GaN (uid GaN) layer 303 may have a thickness in a range of from 500 Å to 30,000 Å. In certain embodiments, the uid GaN layer 303 may have a thickness of at least 7500 Å, at least 10,000 Å, at least 12,500 Å, at least 15,000 Å, or at least 17,500 Å. In certain embodiments, the maximum value of each of the minimum thresholds may be about 30,000 Å. Increasing thickness of the uid GaN layer 303 positioned below the silicon-doped layer 304 decreases defect density in the active region 305, which reduces the probability of non-radiative recombination at defects in the crystal. Reduced defect density and reduced probability of radiative recombination at defects promote improvement of thermal luminous flux droop performance by better maintaining LED radiant flux at elevated temperatures.

In certain embodiments, the silicon-doped GaN (Si-GaN) layer 304 may have a thickness in a range of from 20,000 Å to 70,000 Å, or in a range of from 20,000 Å to 60,000 Å, or in a range of from 23,000 Å to 50,000 Å, or in a range of from 25,000 Å to 40,000 Å. In certain embodiments, the Si-GaN layer 304 may have a thickness of at least 20,000 Å, at least 23,000 Å, at least 25,000 Å, at least 27,000 Å, or at least 30,000 Å, with the maximum value of the preceding minimum thresholds preferably being about 50,000 Å in certain embodiments.

As will be recognized by one skilled in the art, the active region 305 may include any suitable number of quantum wells and barriers having compositions known in the art. A quantum well and barrier in combination may embody a repeat unit, and in certain embodiments, the number of repeat units may be from 1 to 12. In certain embodiments, the thickness of a single well may be in a range of from 15 Å to 35 Å, and the thickness of a single barrier may be in a range of from 25 Å to 150 Å. If only a single repeat unit is provided, then the aggregate thickness of the active region 305 may be in a range of from 40 Å to 185 Å. Similarly, if two repeat units are provided, then the aggregate thickness of the active region 305 may be in a range of from 80 Å to 370 Å; if twelve repeat units are provided then the aggregate thickness of the active region 305 may be in a range of from 480 Å to 2220 Å. For a possible range of from one to twelve repeat units, the aggregate thickness of the active region 303 may be from 40 Å to 2220 Å.

The “cap” (or “electron blocking”) layer 306 may include any suitable III-nitride material such as InAlGaN or AlGaN. In certain embodiments, the cap layer 306 may have a thickness in a range of from 50 Å-500 Å, or from 250 Å-500 Å, or from 300 Å-500 Å, or from 350 Å-450 Å. In certain embodiments, the cap layer 306 has a thickness of at least 300 Å, at least 350 Å, or at least 400 Å, wherein in certain embodiments the foregoing minimum thresholds may be constrained by an upper threshold of 500 Å or 550 Å. Increasing thickness of the cap or electron blocking layer 306 tends to enhance efficacy of electron blocking, which reduces electron overshoot—thereby improving thermal luminous flux droop performance by better maintaining LED radiant flux at elevated temperatures. If the cap layer 306 is excessively thick, however, then at room temperature (e.g., 25° C.) conditions, there may not be sufficient holes available in the active region to promote adequate device performance.

In certain embodiments, concentration of group III material (e.g., aluminum) within the cap layer 306 may be varied with thickness of the layer, in order to alter performance of the cap layer 306.

In certain embodiments, at least a portion of the cap layer 306 may be doped. In certain embodiments, the dopant may be activated at a device operating temperature (e.g., at a temperature of at least 75° C. or at least 85° C.) to make enough holes available to enhance performance of the active region 305. In certain embodiments, the dopant may include Mg, Zn, and/or another suitable p-type dopant. If the cap layer 306 is doped, then the dopant concentration is preferably less than the dopant concentration in the overlying p-AlGaN layer 307. In certain embodiments wherein the cap layer 306 is doped, the dopant concentration of such layer 306 may in a range of from 20% to 30% of the dopant concentration in the p-AlGaN layer 307. In certain embodiments, at least a portion of the cap layer 306 may be uniformly doped. In certain embodiments, at least a portion of the cap layer 306 may be non-uniformly doped. In certain embodiments, at least a portion of the cap layer 306 may be delta-doped with one or more very thin (nearly single atomic layer) thickness discrete or isolated dopant regions. In certain embodiments, at least a portion of the cap layer 306 may be doped with a stepwise variation in concentration. In certain embodiments, at least a portion of the cap layer 306 may be doped according to a linear or nonlinear ramp of dopant concentration. In certain embodiments, a ramped dopant profile may be ramped from low to high dopant concentration in the direction of epitaxial growth of the layer 306; in other embodiments, a ramped dopant profile may be ramped from high to low dopant concentration in the direction of epitaxial growth of the layer 306 In certain embodiments, the entire cap layer 306 may be doped according to one of the above-referenced doping profiles. In other embodiments, only a portion of the cap layer 306 may be doped according to one of the above-referenced doping profiles, such as an “upper” portion distal from the active region 305. In certain embodiments, only a distal half, a distal third, a distal fourth, or a distal fifth of the cap layer 306 may be doped, with each of the foregoing “distal” portions being distal from the active region 305. In certain embodiments, a cap layer may embody increased thickness according to a range as disclosed herein in combination with doping as disclosed herein. In certain embodiments, the dopant concentration, dopant position, and/or doping profile of the cap layer 306 may be selected to provide increased presence of holes at a device operating temperature (e.g., at a temperature of at least 75° C. or at least 85° C.) to improve thermal luminous flux droop performance by better maintaining LED radiant flux at elevated temperatures.

In certain embodiments, the p-AlGaN layer 307 may have a thickness in a range of 50 Å-350 Å. In certain embodiments, the p-AlGaN layer 307 may have an aluminum fraction of from 8%-35% in the III-nitride material (e.g., a composition in a range of Al_{0.08}Ga_{0.92}N to Al_{0.35}Ga_{0.65}N). In certain embodiments, the p-GaN layer 308 may have a thickness in a range of 300 Å-2500 Å, in a range of 400 Å-2000 Å, or in a range of from 500 Å-1000 Å.

Embodiments as disclosed herein may provide one or more of the following beneficial technical effects: enhancing emissions of solid state lighting devices at elevated temperatures by reducing luminous flux droop, enhancing stability of output color of solid state lighting devices at elevated temperatures and elevated operating power, and providing increased luminous efficacy of lumiphor-converted solid state lighting devices at elevated temperatures and elevated operating power.

While the invention has been has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Various combinations and sub-combinations of the structures described herein are contemplated and will be apparent to a skilled person having knowledge of this disclosure. Any of the various features and elements as disclosed herein may be combined with one or more other disclosed features and elements unless indicated to the contrary herein. Correspondingly, the invention as hereinafter claimed is intended to be broadly construed and interpreted, as including all such variations, modifications and alternative embodiments, within its scope and including equivalents of the claims.

1. A solid state lighting device comprising a lumiphoric material having a peak emission wavelength in a yellow range arranged to receive and be excited by light emissions of at least one electrically activated solid state light emitter having a peak emission wavelength in a range of from 428 nm to 440 nm at a solid state light emitter temperature of 25° C., wherein the lumiphoric material comprises a peak excitation wavelength that exceeds the peak emission wavelength of the at least one electrically activated solid state light emitter by at least 20 nm.

2. A solid state lighting device according to claim 1, wherein the solid state lighting device exhibits at least one of the following characteristics (a) to (d):
(a) a luminous flux drop of no greater than 5% when operated at an electrically activated solid state light emitter temperature of 85° C. relative to operation at an electrically activated solid state light emitter temperature of 25° C.;
(b) a luminous flux drop of no greater than 8% at an electrically activated solid state light emitter temperature of 105° C. relative to operation at an electrically activated solid state light emitter temperature of 25° C.;
(c) a luminous flux drop of no greater than 12% at an electrically activated solid state light emitter temperature of 125° C. relative to operation at an electrically activated solid state light emitter temperature of 25° C.; and
(d) a luminous flux drop of no greater than 17% at an electrically activated solid state light emitter temperature of 150° C. relative to operation at an electrically activated solid state light emitter temperature of 25° C.

3. A solid state lighting device according to claim 1, wherein the at least one electrically activated solid state light emitter comprises at least one light emitting diode.

4. A solid state lighting device according to claim 1, wherein the at least one electrically activated solid state light emitter comprises a plurality of electrically activated solid state light emitters.

5. A solid state lighting device according to claim 1, wherein the lumiphoric material comprises one or more phosphors.

6. A solid state lighting device according to claim 1, wherein the lumiphoric material comprises a peak emission wavelength in a range of from 540 nm to 572 nm.

7. A solid state lighting device according to claim 1, wherein the lumiphoric material is spatially segregated from each electrically activated solid state light emitter of the at least one electrically activated solid state light emitter.

8. A solid state lighting device according to claim 1, wherein the at least one electrically activated solid state light emitter comprises an epitaxial structure including a substrate, a buffer layer, an unintentionally doped III-nitride layer overlying the buffer layer, a Si-doped III-nitride layer overlying the unintentionally doped III-nitride layer, a III-nitride active region overlying the Si-doped III-nitride layer, a III-nitride cap layer overlying the III-nitride active region, and at least one p-doped III-nitride overlying the III-nitride cap layer, wherein the unintentionally doped III-nitride layer has a thickness of at least 10,000 Angstroms, and wherein the cap layer has a thickness of at least 300 Angstroms.

9. A solid state lighting device according to claim 8, wherein the unintentionally doped III-nitride layer comprises unintentionally doped GaN, the Si-doped III-nitride layer comprises Si-doped GaN, the III-nitride cap layer comprises InAlGaN, and the at least one p-doped III-nitride layer comprises (i) a p-doped AlGaN layer and (ii) a p-doped GaN layer.

10. A solid state lighting device according to claim 1, wherein the at least one electrically activated solid state light emitter has a peak emission wavelength in a range of from 434 nm to 438 nm at a LED temperature of 25° C.

11. A method comprising illuminating an object, a space, or an environment, utilizing a solid state lighting device according to claim 1.

12. A solid state lighting device comprising a lumiphoric material arranged to receive and be excited by light emissions of at least one electrically activated solid state light emitter, wherein the at least one electrically activated solid state light emitter is arranged to emit light in a blue wavelength range, the lumiphoric material is arranged to emit light in a yellow wavelength range, and the solid state lighting device exhibits at least one of the following characteristics (a) to (d):
(a) a luminous flux drop of no greater than 5% when operated at an electrically activated solid state light emitter temperature of 85° C. relative to operation at an electrically activated solid state light emitter temperature of 25° C.;
(b) a luminous flux drop of no greater than 8% at an electrically activated solid state light emitter temperature of 105° C. relative to operation at an electrically activated solid state light emitter temperature of 25° C.;
(c) a luminous flux drop of no greater than 12% at an electrically activated solid state light emitter temperature of 125° C. relative to operation at an electrically activated solid state light emitter temperature of 25° C.; and
(d) a luminous flux drop of no greater than 17% at an electrically activated solid state light emitter temperature 150° C. relative to operation at an electrically activated solid state light emitter temperature of 25° C.

13. A solid state lighting device according to claim 12, exhibiting each of characteristics (a) to (d).

14. A solid state lighting device according to claim 12, wherein the at least one electrically activated solid state light emitter comprises a light emitting diode including a nominal peak emission wavelength in a range of from 428 nm to 440 nm at a LED temperature of 25° C.

15. A solid state lighting device according to claim 12, wherein the at least one electrically activated solid state light emitter comprises a light emitting diode (LED) including a nominal peak emission wavelength at a LED temperature of 25° C., the lumiphoric material comprises a peak excitation wavelength, and the peak excitation wavelength exceeds the nominal peak emission wavelength by at least 15 nm.

16. A solid state lighting device according to claim 12, wherein the at least one electrically activated solid state light emitter comprises a light emitting diode (LED) including a nominal peak emission wavelength at a LED temperature of 25° C., the lumiphoric material comprises a peak excitation wavelength, and the peak excitation wavelength exceeds the nominal peak emission wavelength by at least 20 nm.

17. A solid state lighting device according to claim 12, wherein the at least one electrically activated solid state light emitter comprises at least one light emitting diode.

18. A solid state lighting device according to claim 12, wherein the at least one electrically activated emitter comprises a plurality of electrically activated solid state emitters.

19. A solid state lighting device according to claim 12, wherein the lumiphoric material comprises a peak emission wavelength in a range of from 540 nm to 572 nm.

20. A solid state lighting device according to claim 12, wherein the at least one electrically activated solid state light emitter comprises an epitaxial structure including a substrate, a buffer layer, an unintentionally doped III-nitride layer overlying the buffer layer, a Si-doped III-nitride layer overlying the unintentionally doped III-nitride layer, a III-nitride active region overlying the Si-doped III-nitride layer, a III-nitride cap layer overlying the III-nitride active region, and at least one p-doped III-nitride overlying the III-nitride cap layer, wherein the unintentionally doped III-nitride layer has a thickness of at least 10,000 Angstroms, and wherein the cap layer has a thickness of at least 300 Angstroms.

21. A solid state lighting device comprising at least one light emitting diode (LED) including a nominal peak emission wavelength in a range of from 428 nm to 440 nm at a LED temperature of 25° C., and a lumiphoric material arranged to receive and be excited by light emissions of the at least one LED, wherein the lumiphoric material comprises a peak excitation wavelength, and the solid state lighting device comprises at least one of the following features (a) and (b): (a) the peak excitation wavelength of the lumiphoric material exceeds the nominal peak emission wavelength by at least 15 nm, and (b) the solid state lighting device is devoid of any lumiphoric material comprising a peak excitation wavelength within 15 nm of the nominal peak emission wavelength.

22. A solid state lighting device according to claim 21, wherein the peak excitation wavelength of the lumiphoric material exceeds the nominal peak emission wavelength by at least 15 nm.

23. A solid state lighting device according to claim 21, wherein the peak excitation wavelength of the lumiphoric material exceeds the nominal peak emission wavelength by at least 20 nm.

24. A solid state lighting device according to claim 21, wherein the solid state lighting device is devoid of any lumiphoric material comprising a peak excitation wavelength within 15 nm of the nominal peak emission wavelength.

25. A solid state lighting device according to claim 21, wherein the solid state lighting device is devoid of any lumiphoric material comprising a peak excitation wavelength within 20 nm of the nominal peak emission wavelength.

26. A solid state lighting device according to claim 21, wherein the LED includes a nominal peak emission wavelength in a range of from 434 nm to 438 nm.

27. A solid state light emitting device according to claim 21, wherein the lumiphoric material comprises a peak emission wavelength in a range of from 540 nm to 572 nm.

28. A solid state lighting device according to claim 21, wherein the LED comprises an epitaxial structure including a substrate, a buffer layer, an unintentionally doped III-nitride layer overlying the buffer layer, a Si-doped III-nitride layer overlying the unintentionally doped III-nitride layer, a III-nitride active region overlying the Si-doped III-nitride layer, a III-nitride cap layer overlying the III-nitride active region, and at least one p-doped III-nitride overlying the III-nitride cap layer, wherein the unintentionally doped III-nitride layer has a thickness of at least 10,000 Angstroms, and wherein the cap layer has a thickness of at least 300 Angstroms.

29. A solid state lighting device comprising a lumiphoric material having a peak emission wavelength in a yellow range arranged to receive and be excited by light emissions of at least one electrically activated solid state light emitter having a peak emission wavelength in a blue range, wherein:
aggregated emissions of the at least one electrically activated solid state light emitter and the lumiphoric material comprise (a) a high temperature luminous flux value when the at least one electrically activated solid state light emitter is operated at 85° C., and (b) a low temperature luminous flux value when the at least one electrically activated solid state light emitter is operated at 25° C., wherein relative luminous flux comprises a ratio of the high temperature luminous flux value to the low temperature luminous flux value;
emissions of the at least one electrically activated solid state light emitter comprise (c) a high temperature radiant flux value when the at least one electrically activated solid state light emitter is operated at 85° C., and (d) a low temperature radiant flux value when the at least one electrically activated solid state light emitter is operated at 25° C., wherein relative radiant flux comprises a ratio of the high temperature radiant flux value to the low temperature radiant flux value; and
a ratio of relative luminous flux to relative radiant flux is greater than or equal to 0.98.

30. A solid state lighting device according to claim 29, wherein the at least one electrically activated solid state light emitter comprises a peak emission wavelength in a range of from 428 nm to 440 nm at a solid state light emitter temperature of 25° C.

31. A solid state lighting device according to claim 29, wherein the lumiphoric material comprises a peak excitation wavelength that exceeds the peak emission wavelength of the at least one electrically activated solid state light emitter by at least 15 nm.

32. A solid state lighting device according to claim 29, wherein the lumiphoric material comprises a peak excitation wavelength that exceeds the peak emission wavelength of the at least one electrically activated solid state light emitter by at least 20 nm.

33. A solid state lighting device according to claim 29, wherein the solid state lighting device exhibits at least one of the following characteristics (a) to (d):
(a) a luminous flux drop of no greater than 5% when operated at an electrically activated solid state light emitter temperature of 85° C. relative to operation at an electrically activated solid state light emitter temperature of 25° C.;
(b) a luminous flux drop of no greater than 8% at an electrically activated solid state light emitter temperature of 105° C. relative to operation at an electrically activated solid state light emitter temperature of 25° C.;
(c) a luminous flux drop of no greater than 12% at an electrically activated solid state light emitter temperature of 125° C. relative to operation at an electrically activated solid state light emitter temperature of 25° C.; and
(d) a luminous flux drop of no greater than 17% at an electrically activated solid state light emitter temperature 150° C. relative to operation at an electrically activated solid state light emitter temperature of 25° C.

34. A solid state lighting device according to claim 29, wherein the lumiphoric material comprises a peak emission wavelength in a range of from 540 nm to 572 nm.

35. A solid state lighting device according to claim 29, wherein the lumiphoric material is spatially segregated from each electrically activated solid state light emitter of the at least one electrically activated solid state light emitter.

36. A solid state lighting device according to claim 29, wherein the at least one electrically activated solid state light emitter comprises an epitaxial structure including a substrate, a buffer layer, an unintentionally doped III-nitride layer overlying the buffer layer, a Si-doped III-nitride layer overlying the unintentionally doped III-nitride layer, a III-nitride active region overlying the Si-doped III-nitride layer, a III-nitride cap layer overlying the III-nitride active region, and at least one p-doped III-nitride overlying the III-nitride cap layer, wherein the unintentionally doped III-nitride layer has a thickness of at least 10,000 Angstroms, and wherein the cap layer has a thickness of at least 300 Angstroms.

37. A solid state lighting device according to claim 36, wherein the unintentionally doped III-nitride layer comprises unintentionally doped GaN, the Si-doped III-nitride layer comprises Si-doped GaN, the III-nitride cap layer comprises InAlGaN, and the at least one p-doped III-nitride layer comprises (i) a p-doped AlGaN layer and (ii) a p-doped GaN layer.
